(19) United States
(12) Patent Application Publication
(10) Pub. No.: US 2007/0042139 A1
(43) Pub. Date: Feb. 22, 2007

(54) Luminescent coating

(75) Inventors: William Robert Cooper, Kilcreggan (GB); Howard Mitchell Jess, Glasgow (GB)

Correspondence Address: MERCHANT & GOULD PC, P.O. BOX 2903, MINNEAPOLIS, MN, 55402-0903, US

(73) Assignee: Luminous Technologies Ltd., Earnhill Place (GB)

(21) Appl. No.: 11/370,226

(22) Filed: Mar. 6, 2006

Related U.S. Application Data
(63) Continuation-in-part of application No. 11/223,458, filed on Sep. 9, 2005, now abandoned.
Application No. 11/223,458 is a continuation-in-part of application No. 09/958,189, filed on Jan. 15, 2002, now abandoned.

(30) Foreign Application Priority Data
Oct. 3, 2000 (GB) 0024164.6

(51) Int. Cl. B05B 5/00; B05D 7/00; C23C 16/52; B44F 1/10

(52) U.S. Cl. 428/29; 427/402; 427/8; 427/160

(57) ABSTRACT

A coating system and method of applying coatings includes applying a first coating having an ultraviolet (UV) indicator therein to an area. The area visually inspected with a UV light and defects are remedied until the area passes the visual inspection. A second coating without a UV indicator is applied over the first coating and visually inspected, with the first coating being visible with a UV light at portions wherein the second coating does not cover the first coating. The second coating is reapplied to portions of the area not passing inspection until the second coating passes inspection. The system also includes three, four or more coating layers in some embodiments with layers having a UV alternated with layers without a UV indicator. The indicator is an inert substance that remains stable to allow for periodic visual inspection over the life of the coating. Visual inspections may be combined with inspections by light metering equipment and a record created for comparison and continued monitoring of the coating system.

This application is a Continuation-in-Part of application Ser. No. 11/223,458, filed Sep. 9, 2005, which is a Continuation-in-Part of application Ser. No. 09/958,189, filed Jan. 12, 2002 which is the National Stage of Application PCT/GB01/01151, filed Mar. 16, 2001, and which application(s) are incorporated herein by reference.

### BACKGROUND OF THE INVENTION

1. Field of the Invention

The present invention relates to a coating system and a method of coating a surface as well as a method for inspecting the quality of the coating at the time of application and continued inspections throughout the life of the coating.

2. Description of the Prior Art

Coatings and particularly protective coatings on surfaces, whether for marine, industrial or domestic uses depend on effective initial application for superior performance. Among factors affecting this application are surface preparation, coating thickness, continuity and number of coats applied. Moreover, subsequent coating damage caused by heat, abrasion, climate, corrosion and impacts must be taken into account when conducting inspections of such coatings.

For many applications, damage due to corrosion and impacts is often difficult to detect. This is especially problematic on surfaces that are difficult to access with detection equipment.

The inspection survey of coatings on aircraft, seagoing vessels, underwater sections of offshore drilling rigs, production platforms as well as land installations such as oil and chemical storage tanks, reaction vessels and industrial plants, rail tank cars and similar structures is time consuming and therefore, costly. Such time consuming inspections require skilled manpower and cause down time for the equipment being inspected. Due to the complicated structure of some of the equipment, it may be difficult to carry out an accurate survey of all the parts of these structures with any degree of certainty.

As more stringent regulations are implemented, requirements have increased the protection for ballast tanks and double hull areas of tankers and require coatings that are sufficiently tough while providing proper protection. It has been found that up to 14% of the time for manufacture of large ships may be spent on coating and inspection. Moreover, annual repair costs due to corrosion of marine tanks in the United States Navy has been estimated at over 64 million dollars. The United States Navy also predicted that if this cost could be cut by better quality initial application and inspection, the savings could reach 2.3 billion dollars over twenty years.

Many prior fluorescent and luminescent paints have required that a large proportion of the coating be a visual indicator. Such a large concentration of the additive may negatively affect the performance of the coating. Moreover, many types of pigments alter the coating color and appearance. Such indicators are typically organic based compositions that may deteriorate and lose their usefulness over time, often in as little as three months time. The organic indicators may also migrate between coats so it isn't clear whether a particular coating has been applied, particularly in multi-coat systems. The layer with an indicator may migrate into the next layer without an indicator, so that it may not be clear after time has passed whether the second layer was satisfactorily applied. Many indicators are not luminous for a long period, requiring constant light and forcing inspection of a smaller area at any given time. In addition, many indicators do not show fluorescence in a color that is easy for the human eye to detect, so that the contrast between the coating and the uncoated areas are not readily detected.

Prior inspection techniques have required bulky equipment that is not sufficiently portable to provide access for inspecting many structures that need to be coated. Moreover, such sensitive equipment is expensive and requires much care and calibration. It can be appreciated that if the portability of the inspection equipment is increased and could be hand held, the coatings and their inspection have greater utility. Such easily held inspection equipment should also have sufficient light to clearly and brightly illuminate the area to be inspected.

It can be seen then that a new and improved coating and method for coating and inspection is needed. Such a coating and method should provide for simple effective application and reliable overall coating. Inspections should be easily accomplished and allow for inspection during the application process without having to wait for the coating to set and for inspections periodically throughout the life of the coating after is has been applied, to check for wear, corrosion, impacts or other coating deterioration. Such a system and method should provide a clear indication of coating that distinguishes easily from uncoated areas. The present invention addresses these as well as other problems associated with coating systems as well as application and inspection of protective coatings.

### SUMMARY OF THE INVENTION

The present invention is directed to an improved coating system and to an improved method of applying and inspecting coatings. A coating system of the present invention includes an optically active additive that provides a visual indication of gaps, holes and other defects in the coating when viewed under certain types of light.

According to a first embodiment, a coating with a visual indicator additive is applied to a substrate. A projector, typically an ultraviolet (UV) light, although light in other wavelengths is also contemplated by the present invention, and a light meter are positioned a predetermined distance from the coated surface and readings are taken and compared to a base reading. Readings falling below a predetermined level indicate that the coating is applied too thin or other gaps or flaws exist. Such defects can then be remedied with further selective application as necessary. A camera is used to create a record of the coating for comparison for further inspections over the life of the coating. The visual indicator is an inert inorganic additive as opposed to prior organic additives, which have a short life span. The stable inorganic visual indicator provides for periodic inspections over the life of the coating. The photographs provide comparison points for wear and other deterioration of the coating over time. The use of the light meter and photographic record may be combined with other initial visual inspection for improved quality control at the time of the initial application of the protective coating.

According to another embodiment, the present invention provides a method of initial application and inspection. The coating includes a visual indicator that is activated, for example, with ultraviolet light. A portable UV light, preferably a hand held light, is used after an area has been coated. The light is directed against the coated surface and missed or inadequately coated areas appear as dark patches or spots under direct visual inspection. The defects may be corrected and the area reinspected without the applicator leaving the work area. The coating is applied as necessary until the entire area passes inspections. The coating and indicator used may be inspected while the paint is wet or the coating is curing so that the application and coating is occurring interactively, rather than waiting for the coating to set and then returning to conduct inspections and reapplication as may be necessary.

For some uses a second coating is necessary. For such applications according to the present invention, a first coating is applied with a visual indicator as described above. When the first coating passes inspection, a second layer is applied. The second coating does not contain an added visual indicator so that when inspected, the visual indicator of the first coating shows through where there are gaps in the second coating. As with the first layer, the second layer may be inspected while setting so that application, inspection and reapplication as necessary may be conducted at an area until that area is coated satisfactorily and passes inspection. It can be appreciated that more layers may be added over the first two layers, alternating layers having a visual indicator with layers without an indicator.

The inert inorganic visual indicators of the present invention provide for a long life so that the coating may be easily inspected with a hand held UV light periodically after initial applications. The optical additives also provide a visual indication of stress in the coating and the substrate as cracks and other structural problems will appear under visual inspection. Other types of deterioration such as abrasions, corrosion and impacts are easily detected under visual inspection.

These features of novelty and various other advantages that characterize the invention are pointed out with particularity in the claims annexed hereto and forming a part hereof. However, for a better understanding of the invention, its advantages, and the objects obtained by its use, reference should be made to the drawings that form a further part hereof, and to the accompanying descriptive matter, in which there is illustrated and described a preferred embodiment of the invention.

### BRIEF DESCRIPTION OF THE DRAWINGS

Referring now to the drawings, wherein like references and numerals indicate corresponding structure throughout the several views:

FIG. 1 is a side sectional view of a substrate having a first coating layer applied thereto according to the principles of the present invention;

FIG. 2 is a side sectional view of the substrate shown in FIG. 1 with the first coating layer further applied to cover defects detected in the first coating layer;

FIG. 3 is a side sectional view of the substrate shown in FIG. 2 with a second coating layer applied thereto;

FIG. 4 is a side sectional view of the substrate shown in FIG. 3 with the second coating layer applied further to cover defects detected in the second coating layer;

FIG. 5 is a top plan view of a substrate such as that shown in FIG. 1 under a detecting light;

FIG. 6 is a top plan view of the substrate shown in FIG. 3 under a detecting light;

FIG. 7 is a diagrammatic view of a first method of applying a coating and inspecting according to the principles of the present invention;

FIG. 8 is a diagrammatic view of a second method of applying a coating and inspecting according to the principles of the present invention;

FIG. 9 is a diagrammatic view of an area to be coated showing multiple work zones;

FIG. 10 is a diagrammatic view of a third method of coating and inspecting a coating according to the principles of the present invention; and

FIG. 11 is a side sectional view of a fourth embodiment of the present invention with four coating layers applied to a substrate according to the principles of the present invention.

### DETAILED DESCRIPTION OF THE PREFERRED EMBODIMENT

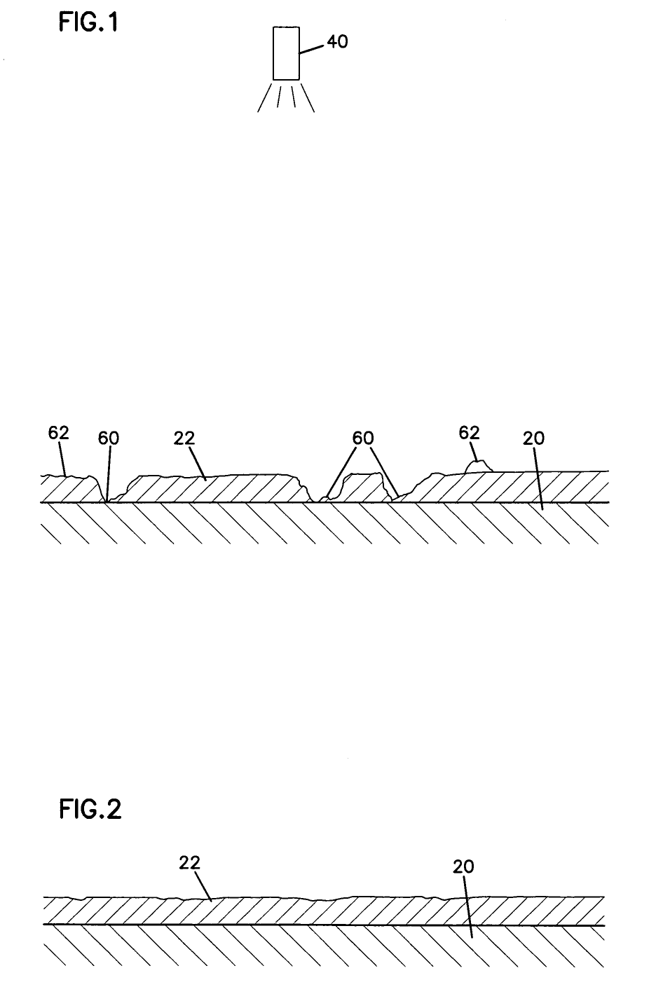

Referring now to the drawings, and in particular FIG. 1, there is shown a surface or substrate 20 having a first protective coating 22 applied thereto. The coating 22 may be a coating of paint, sealant or other protective layer. The composition of the coating 22 preferably includes an optically activated additive (OAA) such as a luminescent additive acting as a visual indicator in selected types of light such as ultraviolet.

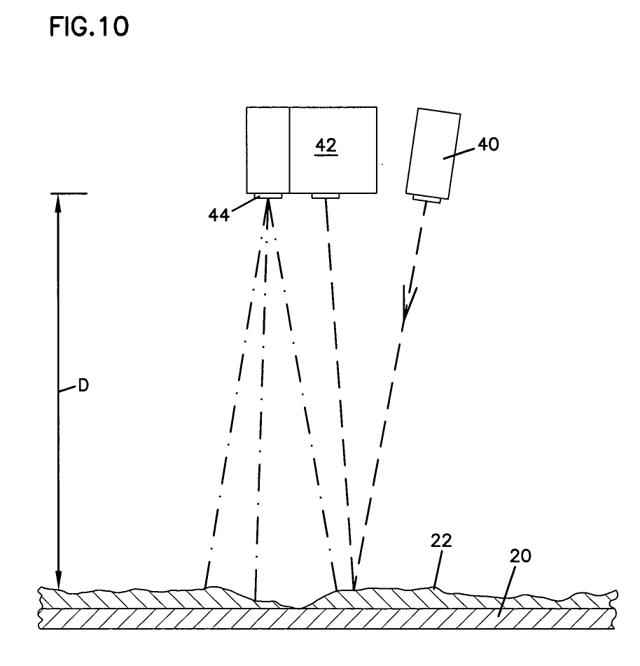

According to one aspect of the invention shown in FIG. 10, inspection occurs with a projector 40, a camera 42, preferably a digital camera, and a light meter 44, measuring light emitted from the projector 40. The camera 42 and light meter are preferably positioned a predetermined distance D from the first coating 22 so that its thickness may be determined with great precision.

Prior to coating, for example, a ship's ballast tank, a proprietary paint suitable for the application, typically a marine grade epoxy based paint for such a use, has added to it an indicator such as a luminescent pigment in a proportion by weight of less than 10% and preferably less than 1% of the epoxy based paint, and more preferably in a concentration of about 1-1.5% by weight.

The projector 40 is fixed at a known distance from substrate 20, the ballast tank surface, and then illuminates the substrate 20 with ultraviolet (UV) light in the range of about 360-400 nm from. The digital camera 42 and the optical meter 44 are fixed at a known distance from surface 20. The light meter 44 is then calibrated to “zero coating”. Zero coating is preferably deemed to be indexed to 100 for example.

The epoxy paint with OAA is then applied as coating 22 and the UV lamp 40 is then switched on and shone all over the coating to see if darker areas show thin coating or very dark patches show holidays or defects. Thin or absent coating can be recorded by directing the meter 44 at the defective area so that the calibrated meter will read slightly less than 100 or 100 for zero coating. The defects can then be remedied and a recording of the coating can be finally made by the digital camera 42 with a coincident meter recording, which should show the 100 according to a predetermined table derived from the paint manufacturer. This enables the coating's thickness to be recorded quickly without resort to conventional complicated and time-consuming methods. In one embodiment, for a more precise visual record the camera is fitted with a filter. The filter eliminates washout, which may appear with no filter.

If required, a second non-luminescent coating 24 can be applied over the coating 22 and the same monitoring technique can be used to detect defects or voids, which show up brightly through the second coating 24.

Referring now to FIG. 1, the present invention also provides a method for direct visual inspection. After the first coating 22 is applied to the substrate 20, a visual inspection may occur using a UV lamp 40, preferably a hand held light. Such a hand held UV lamp 40 emits a UV light, commonly referred to as a black light that may be in the form of a UV flashlight held by an inspector. Areas that have not been covered by the first coating 22 do not glow and appear as dark patches against the glowing first coating 22, such as shown in FIG. 5. Such flaws or defects 60 are noted for touchup or other recoating. Moreover, the coating glows a first color under black light, such as greenish yellow, while particles and other impurities 62 on the coating 22 glow a different color under the black light, such as bluish, so that such particles may be coated over or the substrate 20 may be cleaned and recoated. Although many colors such as red or blue may be used as an indicator, the coating 22 of the present invention is preferably a vivid yellow-green hue. It has been found that the human eye is very sensitive to yellow-green or similar hues, such as is commonly used on emergency vehicles, particularly in low light. The use of such an easily perceived color makes inspection process easier as coated areas versus uncoated areas are quickly and precisely distinguished. Moreover, defects such as over spray, micro-cracking and other common defects are more clearly shown, both on initial application and on periodic follow up inspections.

It can be appreciated that in order to accomplish such an inspection, an easily portable UV light 40 and preferably a small hand held UV light, is particularly beneficial. Quarton, Inc., of Taiwan, having a U.S. company, Quarton USA Inc. in Walnut, Calif. manufactures such a portable lightweight hand held UV flashlight. Moreover, the UV light is cordless and fits into a pocket or one hand of the user so that it may be easily stored in an inspector's pocket while not in use. Prior devices that could be carried could not fit into the hand of the user and had carrying handles. The greater portability in light of the coating equipment that must be carried provides for inspection while wet without making application of the coatings more difficult. The UV flashlight has a larger reflector than prior UV lights that extends all the way to the bottom of the cavity for the UV bulb, providing a brighter light that improves inspection. The brighter light of the present invention and the use of additives with indicators that the human eye is very sensitive to work together to even further improve the inspection process.

Moreover, the optically active additives to the first coating 22, which are commercially available, such as from Luminous Technologies, Ltd. of Greenock, United Kingdom, provide a clear visual indication even while the coating 22 is wet. Therefore, the inspection may take place almost simultaneously with the application and before the first coating 22 sets, such as for example, paint becoming fully dry or sealant becoming cured. The interactive application of coating 22 to an area and direct visual inspection accelerates the application process as there is no need to wait for the coating 22 to set. Moreover, as the light 40 is a hand held portable light that may be carried with the applicator equipment, the inspection can be conducted by the applicator. As the light 40 is typically carried by the applicator in a pocket, there is no need to leave the application area to retrieve separate inspection equipment. The application inspection process is therefore greatly accelerated. It has been found that this additive provides superior performance as it can be added in concentrations at least as low as 1-1.5% by weight without affecting the performance of the coating while still providing satisfactory visual indication. The additive is preferably an inert inorganic crystalline material that does not migrate into or between subsequent coatings over time. It can be appreciated that an inert crystalline additive works in all types of coatings and does not dissolve or deteriorate, allowing for periodic inspections of the coating 22 for many years continuing over the life of the coating.

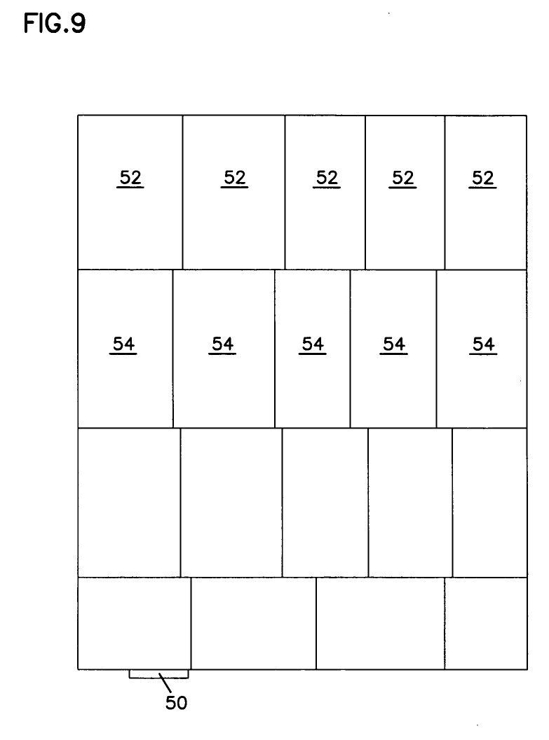

Referring now to FIG. 9, the method may be applied to a specific area in a highly efficient manner. According to one method of the present invention, an entry point 50 provides access to an entire space. Coating begins at a first area 52 remote from the entry point. The first area 52 is coated and inspected, with detected defects being coated until the first area 52 is satisfactory. The applicator then moves to a second area 54 and repeats the coating and inspection process. The applicators performing the coating continue to move from the farthest areas from the entry point 50 comparable to the first area 52 and work to successively closer second areas 54 until an entire space is coated and inspected and the applicator is back at the entry point 50. It can be appreciated that with improved initial application, only one coating 22 may be needed for many uses. The use of the stable inert additive allows for continued inspection throughout the life of the coating 22. Moreover, the initial visual inspection may be quickly and easily recorded using the light meter 44 and digital camera 42 for continued monitoring and comparison.

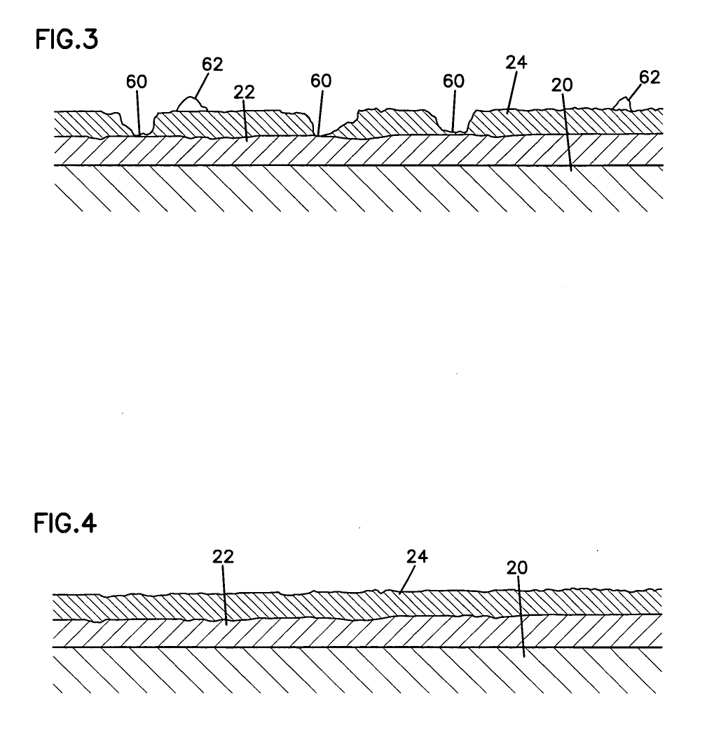

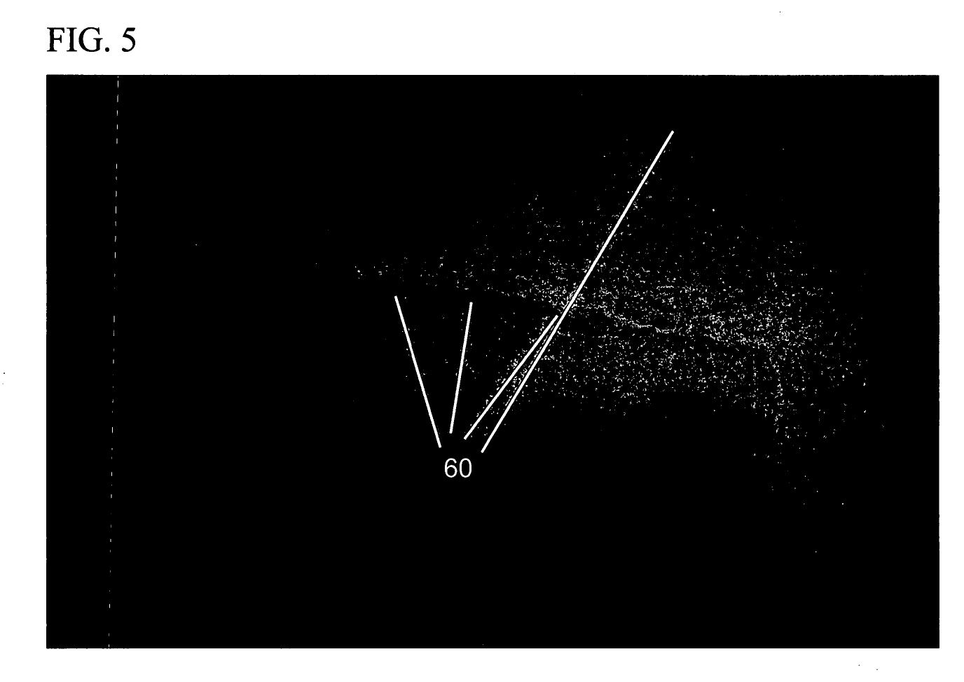

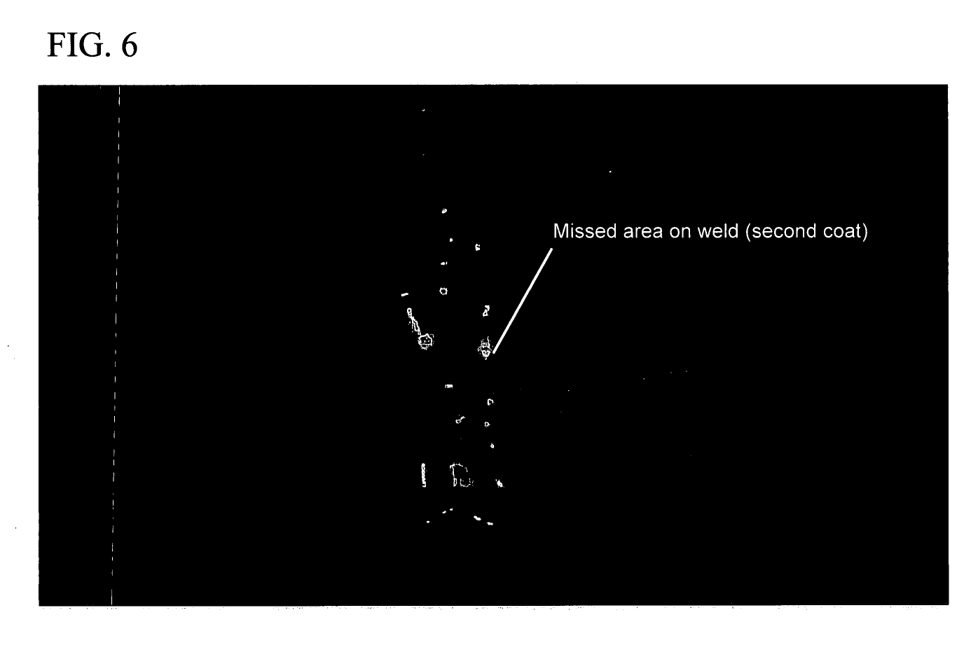

Referring now to FIG. 3, there is shown a further embodiment and method according to the present invention. As shown in FIG. 3, a second coating 24 is applied over the first coating 22 after the first coating 22 has passed inspection. The second coating 24 does not include a visual indicator and provides a stark contrast to the first coating 22, which does not have a visual indicator. Therefore, when visually inspected with a UV light, the UV indicator in the first layer 22 shows through any defects 60 or other discontinuities in the second layer 24. In this manner, the opposite visual contrast is obtained as compared to viewing only the first layer 22 under UV light. If the second layer 24 is satisfactorily applied so that there is continuous coverage without defects, no visual indicator glows under the UV light. If defects 60 do show through, they will appear as bright luminescent areas in a manner as generally shown in FIG. 6. Once the defects 60 have been identified, according to the second method, the second coating 24 is applied further so as to cover the defects, as shown in FIG. 4 and then inspected again. This process of application and inspection with the second coating 24 is repeated until all defects have been eliminated and the second coating 24 passes inspection.

It can be appreciated that with the present invention, simple and reliable methods of application and inspection are obtained for either one, two or other multiple coating layer systems. In addition, it can be appreciated that in either system, inspection occurs after each layer is applied before that layer is completely set without negatively affecting the quality of the coating or inspection. In other words, interactive inspection and coating occurs while the paint is still wet. The two coatings may also be inspected with the light meter 44 and digital camera to create a visual record for continued monitoring over the life of the coatings.

According to a further aspect of the present invention, after the second layer 24 has been applied as shown in FIG. 4, periodic inspections may continue to monitor the condition of the coatings over the life of the coatings. It can be appreciated that with either one or more layer systems, the coatings may indicate not only areas where the coating is failing, but also areas of stress and other structural deformation of the substrate as indicated by cracking or wear in the coating.

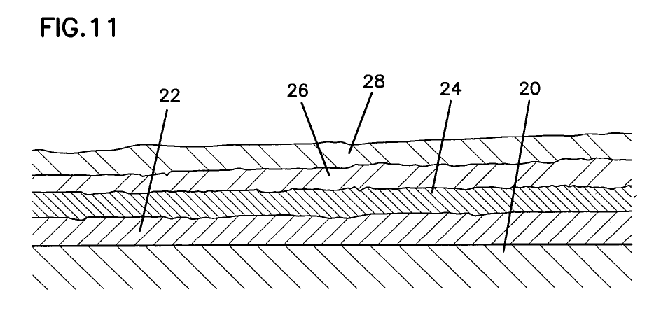

Referring now to FIG. 11, there is shown a further embodiment of the present invention, having more than two layers. As shown in FIG. 11, a third layer 26 containing an OAA added is applied over the second layer 24. The third layer 26 preferably glows a different color than the first layer 22 so that it can be differentiated under visual inspection. The third layer is applied and inspected in a manner similar to that for the first layer 22. For some uses, a fourth layer 24 without an additive is applied. The fourth layer 28 is applied and inspected in the same manner as the second layer 24. It can be appreciated that even more layers may be added according to the present invention as needed, alternating layers with a visual indicator with layers without an additive.

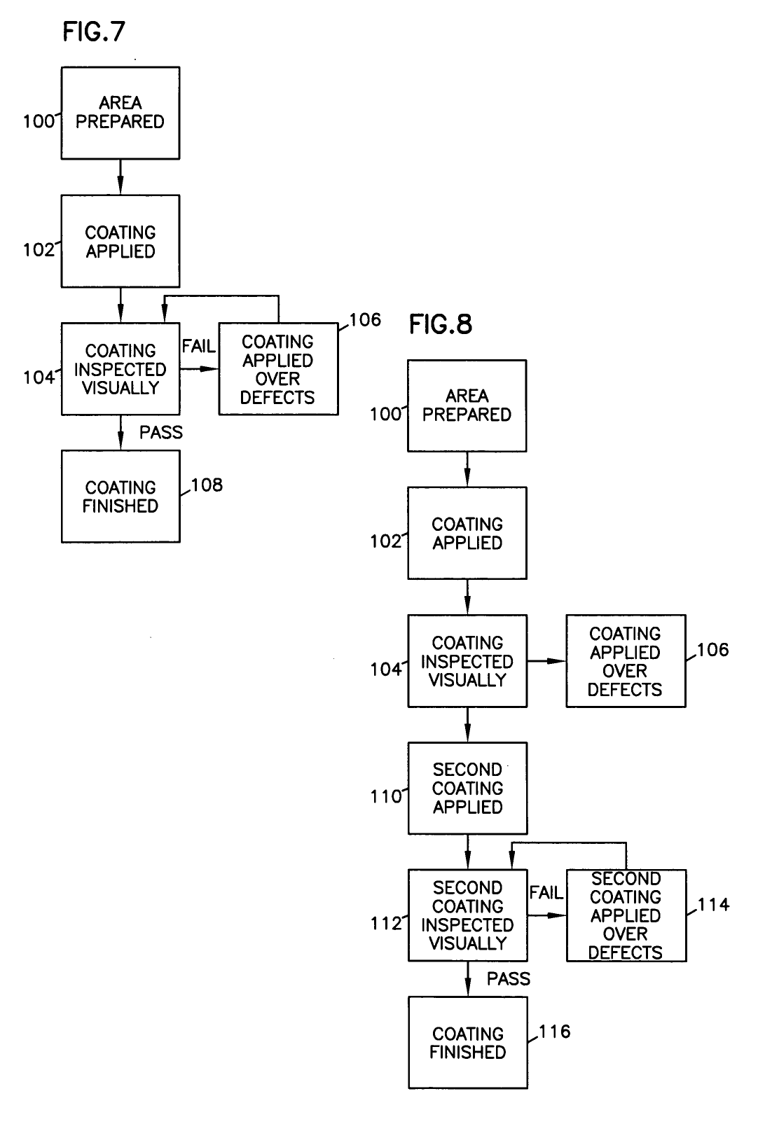

As shown in FIG. 7, the steps for the method shown in FIGS. 1-2 and 5 are shown. The area is first prepared as at step 100, and a first coating is applied over the prepared area as shown at step 102. Visual inspection occurs with a portable UV light at step 104. If the coating inspection passes, the coating of the area is complete and another area may be coated and inspected. This may continue over other areas until the project is completed. Moreover, the method preferably has applicators working from a remote point to points successively closer to a point of entry.

If the coating does not pass inspection at step 104, the coating is applied over the defects at step 106, and direct visual inspection again takes place. If defects are still detected, further coating is applied. If no defects are detected, the coating at the first area is finished as indicated at step 108, the applicator may move to another area. This process is repeated until inspection is passed. It can be appreciated that with a hand held UV light, application and visual inspection may occur without workers leaving the area being coated until that area is finished.

Referring now to FIG. 8, there is shown the method for the embodiment of FIGS. 3, 4 and 6. In such a method, steps 100-108 are repeated for the first layer. When the first layer has been applied in a satisfactory manner as described above for FIG. 7 and properly dried or cured to accept a second layer, the second layer is applied as at step 110. Visual inspection occurs at step 112 and if defects are detected, the second coating is reapplied as at step 114. Further inspection occurs at 112 and applications are made as necessary at step 114 until no defects are detected and inspection is passed and the coating process is finished as shown at step 116. As shown in FIG. 9, in one embodiment of this method, the applicator works from a far point performing the steps discussed above and works successively closer to a point of entry.

It is to be understood, however, that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

What is claimed is:

1. A method of applying coatings comprising:
applying a first coating having an ultraviolet (UV) indicator therein to an area;
visually inspecting the area for defects with a UV light;
reapplying the first coating to portions of the area not passing inspection;
visually inspecting and reapplying the first coating until inspection is passed;
applying a second coating without a UV indicator over the first coating;
visually inspecting the area for defects wherein the first coating is visible with a UV light in portions wherein the second coating does not cover the first coating;
reapplying the second coating to portions of the area not passing inspection; and
visually inspecting and reapplying the second coating until inspection of the second coating is passed.

2. A method according to claim 1, wherein the inspecting is conducted prior to the coating setting.

3. A method according to claim 1, wherein the UV light comprises a cordless hand held UV light.

4. A method according to claim 1, further comprising inspecting the area after a period of time has passed.

5. A method according to claim 1, wherein the indicator shows a first color and contaminates show a second color and wherein defects in the second coat are indicated by the first color.

6. A method according to claim 1, wherein the first coating is inspected while wet.

7. A method according to claim 1, wherein the inspecting is conducted with a hand held light source.

8. A method according to claim 1, wherein the UV light source comprises a cordless hand held flashlight.

9. A method according to claim 1, wherein the indicator comprises an inorganic indicator.

10. A method according to claim 1, wherein the indicator comprises an inert indicator.

11. A method according to claim 1, further comprising applying a third coating having a second indicator over the second layer and visually inspecting and reapplying the third coating until inspection of the third coating is passed.

12. A method according to claim 1, further comprising applying a fourth coating without a UV indicator over the third layer and visually inspecting and reapplying the fourth coating until inspection of the fourth coating is passed.

13. A method for applying a coating to a surface area, comprising:
entering the surface area at an entry point;
applying a coating having an ultraviolet (UV) indicator to a first area at a distant location from the entry point;
visually inspecting the first area with a portable UV light;
reapplying and visually reinspecting the first area until the first area passes inspection;
applying the coating and visually inspecting with the portable UV light over other areas until passing inspection and moving successively closer to the entry point until the surface area is coated and passed inspection.

14. A method according to claim 13, wherein the inspecting is conducted prior to the coating setting.

15. A method according to claim 13, wherein the portable UV light comprises a cordless hand held UV light.

16. A method according to claim 13, further comprising inspecting the area after a period of time has passed.

17. A method according to claim 13, wherein the indicator shows a first color under UV light and contaminates show a second color

18. A method according to claim 13, wherein the first coating is inspected while wet.

19. A method according to claim 13, wherein the inspecting is conducted with a portable light source.

20. A method according to claim 13, wherein the light source comprises a hand held light source.

21. A method according to claim 13, further comprising:
after the first coating passes inspection, applying a second coating without an ultraviolet (UV) indicator over the first area of the first coating,
visually inspecting the first area with a UV light;
reapplying the second coating to portions of the first area not passing inspection;
visually inspecting and reapplying the second coating as necessary until the first area passes inspection; and
moving successively closer to the entry point until the surface area is coated and passed inspection.
maintaining an uncoated area between the application area and the entry point.

22. A method of inspecting a coating system having an optically active indicator, comprising:
directly visually inspecting the coating system under a UV light at initial application and or periodically after the initial application to monitor deterioration of the coating to determine whether recoating is necessary.

23. A method according to claim 22, wherein the indicator comprises an inorganic inert indicator.

24. A method of applying a coating material to a surface, comprising:
applying a layer of the coating material having an ultraviolet (UV) indicator to the surface, while the coating is still wet, directing a UV light to the coating to inspect for defects in the layer of the coating material;
applying further coating material to the surface over portions that do not pass inspection;
conducting further inspections and applying further coating material until the entire surface passes inspection.
further comprising taking a photograph of the area.

25. A coating system comprising:
a first coating including a visual indicator applied to a substrate and capable of visual inspection while setting, the first coating providing continuous coverage of the substrate;
a second coating without a visual indicator applied to the substrate over the first coating and capable of visual inspection indicated by the first layer being visible while the second coating is setting.

26. The coating system according to claim 25, wherein the coating comprises an inert inorganic optical additive.

27. The coating system according to claim 25, wherein the visual indicator has a concentration of 1-1.5% by weight.

28. The coating system according to claim 25, wherein the indicator comprises a yellow green color under UV light.

29. The method according to claim 1, further comprising photographing the coated area with a camera having a yellow green filter.

30. The method according to claim 3, wherein the cordless hand held UV light source comprises a full reflector.

31. The method according to claim 3, wherein the cordless UV light source is configured to fit into one hand of an inspector.

32. The method according to claim 30, wherein the cordless UV light source is configured to fit into one hand of an inspector.
